(19) United States
(12) Patent Application Publication
(10) Pub. No.: US 2015/0243472 A1
(43) Pub. Date: Aug. 27, 2015

(54) Electron Microscope and Sample Movement Device

(71) Applicant: Hitachi High-Technologies Corporation, Minato-ku, Tokyo (JP)

(72) Inventors: Hideki Kikuchi, Tokyo (JP); Kota Ueda, Tokyo (JP); Kouichirou Saitou, Tokyo (JP)

(21) Appl. No.: 14/422,436

(22) PCT Filed: Jun. 26, 2013
(86) PCT No.: PCT/JP2013/067430

§ 371 Date: Feb. 19, 2015

(30) Foreign Application Priority Data
Aug. 20, 2012 (JP) 2012-181303

(51) Int. Cl. H01J 37/20; H01J 37/26; H01J 37/18

(52) U.S. Cl. CPC H01J 37/20; H01J 37/185; H01J 37/26

(57) ABSTRACT

The present invention is intended to reduce drift in a sample which occurs because of distortion in an O-ring which seals off from the atmosphere a sample chamber in which vacuum is retained. Provided is an electron microscope, wherein a sample holder (2) is inserted in a column (1), comprising: an O-ring (4) which makes airtight the column (1) of the electron microscope and the sample holder (2); a slider tube (30) which slides in the longitudinal direction of the sample holder (2) and positions the sample holder in the longitudinal direction; a bellows (32) which makes airtight the slider tube (30) and the column (1); a means (10) for driving the slider (30) in the longitudinal direction of the sample holder (2); and a holder umping part (40) which positions the sample holder (2) in the longitudinal direction. The electron microscope further comprises a sample movement device which has an elastic material (31) which connects the holder umping part (40) and the slider tube (30).

### TECHNICAL FIELD

The present invention relates generally to charged particle beam apparatuses and sample-moving devices, and more particularly to a sample micromotion stage for reducing sample drifts to thereby permit photographing or shooting of distortion-lessened images at high throughputs.

### BACKGROUND ART

Using a charged particle beam apparatus, especially, transmission electron microscope (TEM), observation has been performed at magnifications capable of directly observing atoms. A sample to be observed is processed by a focused ion beam apparatus or the like into a thin piece on the order of several tens of nm, which is then mounted on a sample table. This sample table is attached to a sample holder and is introduced through an pre-evacuation chamber (airlock room) into a column which has been evacuated to approximately 10 5 Pa. In order to determine the position of such sample under observation, a sample movement device is driven in three respective axis directions, when defining a vertical direction as Z-axis and also defining in-plane axes at right angles to the axis as X-axis and Y-axis respectively. In addition, in order to determine the sample's crystal orientation, it is driven in rotation directions (α-direction and (β-direction, respectively) with the X-and Y-axis directions being as respective axes. Usually, the X-axis is defined as the longitudinal direction of sample holder whereas the Y-direction is defined as a direction perpendicular to the X-axis and Z-axis.

To determine an observation region in the atomic level, a drive mechanism capable of performing step motions of several nm for each axis has been chosen.

Regarding a holder driving scheme used for the sample movement device, a technique is contrived for driving in the X-direction while letting the sample holder's leading end be in contact as disclosed in Patent Literature 1. In addition, as disclosed in Patent Literature 2, a technique is also devised for providing a step-like difference at one part of the sample holder and for causing this step-like difference to come into contact with an X-axis drive mechanism.

As for drift factors, although each axis drive mechanism is rendered operative in order to determine the sample observation position, the so-called sample drift phenomenon can take place-that is, the sample behaves to perform undesired movement even after having deactivated the drive mechanism, which movement is due to gear backlash of the drive mechanism and deformation of the drive mechanism per se.

Other factors of the sample drift phenomenon include thermal deformation of the holder in a temperature relaxation process, which deformation is due to a difference in temperature between the holder and column at the time of holder introduction. As a remedy for this factor, a technique for using low heat expansion material is devised as disclosed in Patent Literature 3.

### CITATION LIST

### Patent Literature

Patent Literature 1: JP-A-2004-214087

Patent Literature 2: JP3736772 (B2)

Patent Literature 3: JP-A-2010-165649

### SUMMARY OF INVENTION

### Technical Problem

In the case of performing high-magnification observation using a charged particle apparatus, the following problem occurs: image distortion takes place with tiny movement (drift) of the sample, which is not intended by an apparatus operator. Usually, the drift amount becomes maximal immediately after having introduced a sample that was loaded in the sample holder into the charged particle apparatus. This factor is as follows: the thermal deformation caused by a temperature difference between the sample holder and the column of charged particle apparatus and the distortion of O-ring provided in the sample holder for sealing a vacuum-retained sample chamber and atmosphere apply elastic force to the holder, resulting deformation of the sample holder due to release of the elastic force.

Also note that even in the process of sample observation, with movement in the sample holder longitudinal direction of a sample micromotion mechanism, the O-ring provided in the sample holder is undergoing elastic deformation due to the presence of friction force produced as a result of mutual rubbing of the O-ring against a vacuum seal plane at all times.

### Solution to Problem

An electron microscope with a sample holder being inserted into a column, the electron microscope including: an O-ring which makes airtight the column of the electron microscope and the sample holder; a slider tube which slides in a longitudinal direction of the sample holder and performs positioning of the sample holder in the longitudinal direction; a bellows which makes airtight the slider tube and the column; means for driving the slider tube in the longitudinal direction of the sample holder; and a touching member which performs position determination of the sample holder in the longitudinal direction, characterized by further including a sample movement device which has an elastic material for connection of the touching member and the slider tube.

### Advantageous Effects of Invention

In high-magnification observation using the electron microscope, it becomes possible to acquire good images owing to the ability to lessen sample drifts. It is also possible to shorten the length of a wait time taken until sample drifts have lowered; thus, it becomes possible to improve the throughput.

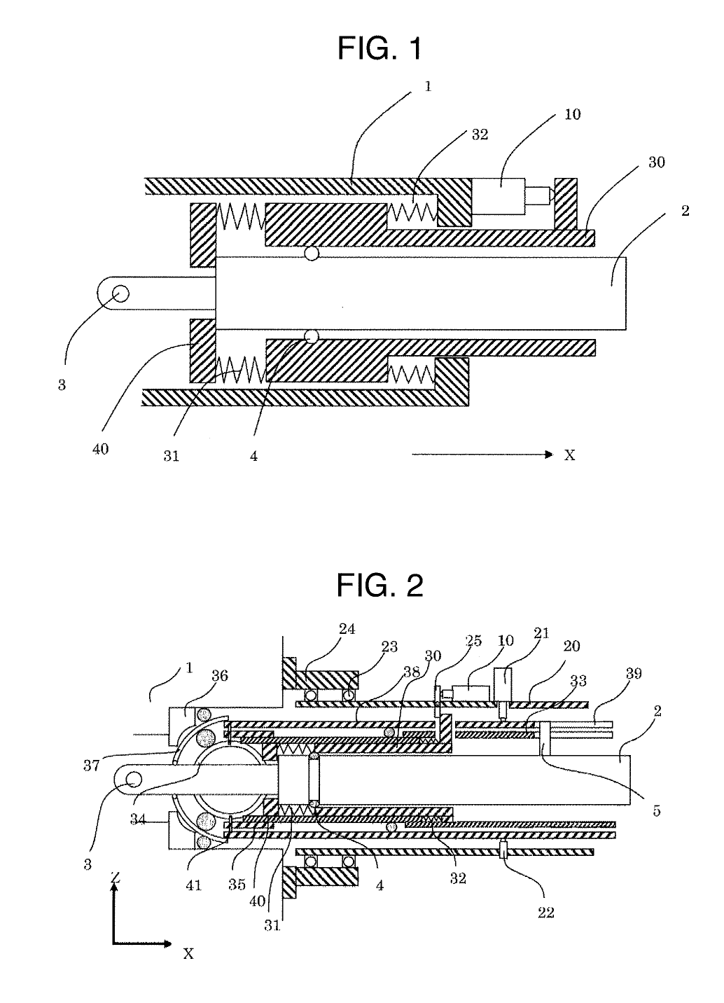

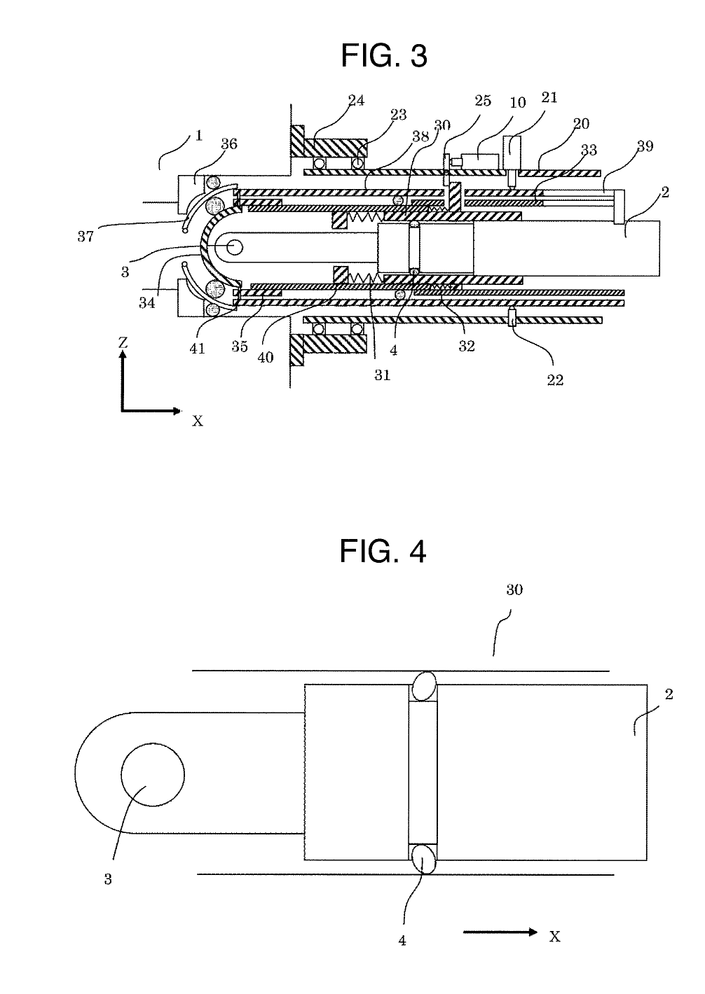

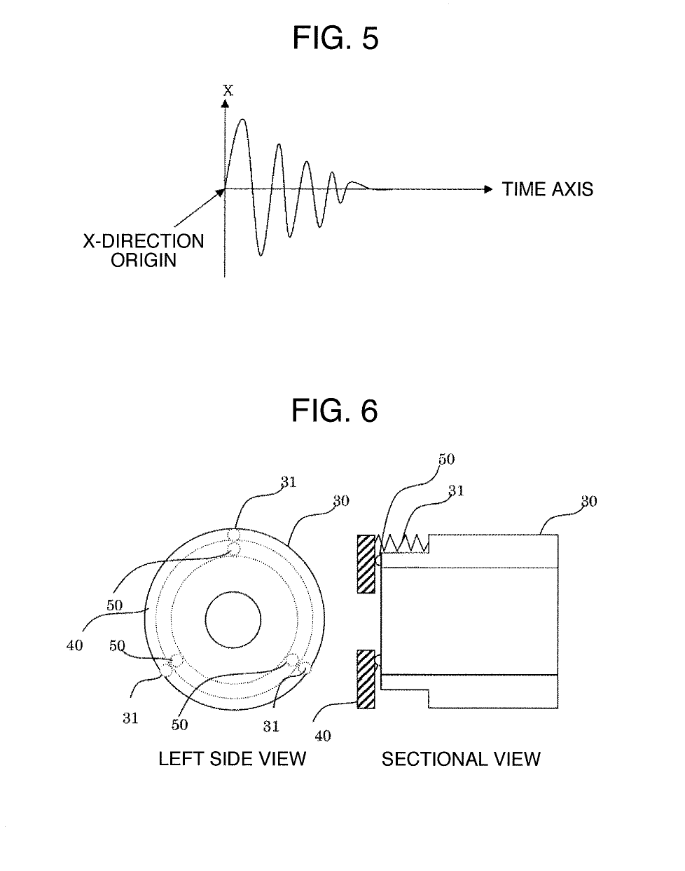

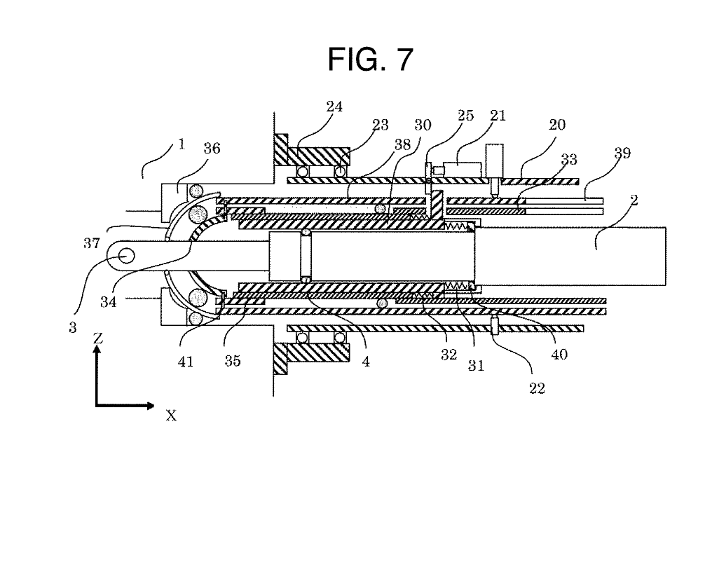

### BRIEF DESCRIPTION OF DRAWINGS

[FIG. 1] A sample movement device of the present invention.

[FIG. 2] A sample movement device of this invention.

[FIG. 3] A sample movement device of this invention.

[FIG. 4] A shape of O-ring provided in a sample holder.

[FIG. 5] Motion of the sample holder at the time of removing O-ring's distortion.

[FIG. 6] An embodiment of holder-touching part.

[FIG. 7] An embodiment of holder-touching part.

### DESCRIPTION OF EMBODIMENTS

A structure embodying the present invention will be explained using an electron microscope which permits insertion of a sample holder of the side entry type shown in FIG. 1. FIG. 1 is a cross-sectional diagram of a sample movement device of this invention. A slider tube 30 is coupled via a bellows 32 to a column 1 of the electron microscope. The slider tube 30 and holder-touching part 40 are fixed by an elastic material 31. In the case of driving a sample holder 2 in a longitudinal direction thereof, an X-driving linear mechanism 10 fixed to the column 1 is rendered operative.

When introducing the sample holder 2 into the column 1, an O-ring 4 provided in the sample holder 2 exhibits sliding movement with an inner wall of slider tube 30 and is then position-determined in the longitudinal direction by the holder-touching part 40. The slid O-ring 4 deforms and becomes the cause of sample drift.

After having introduced the sample holder into column 1 and then position-determined at a final position, the sample holder is pressed to the X-direction minus side in FIG. 1; thereafter, a position that was pushed back by the spring force of elastic material 31 is determined to be the final holder position, thereby alleviating the O-ring deformation.

Another embodiment of this invention will be explained using FIG. 2. A spherical surface bracket 36 fixed in the column 1 is in contact with a spherical supporting point 37. An air-lock cylinder containing therein the spherical supporting point 37 performs head-bobbing motion with the center of spherical supporting point 37 being as its axis; as a result, it becomes possible to force a sample 3 to move in Z-direction (vertical direction) and Y-direction (direction at right angles to the sheet surface). To drive the sample in the Z-direction, a Z-driving linear mechanism 21 fixed to rotation tube 20 is activated. The Z-driving linear mechanism 21 always receives repulsive force by a Z-spring 22 placed at the anti-pole thereof. Another linear mechanism, not depicted, capable of driving in a direction perpendicular to the sheet surface is used to drive the sample holder 2 in Y-direction.

[Installation of X-Micromotion Mechanism]

An explanation will be given of installation of an X-micromotion mechanism. As shown in FIG. 2, the X-driving linear mechanism 10 is attached to the rotation tube 20 that is coupled to a base 24 via a bearing 23. The drive force of X-driving linear mechanism 10 is transmitted to the slider tube 30 by a lever mechanism 25 having a supporting point provided to the rotation tube, thereby driving the sample holder 2 in X-direction. The slider tube is connected by bellows to an inner cylinder 33. A contact portion of the lever mechanism 25 and slider tube 30 necessitates a slip mechanism for the Z-axis and Y-axis driving of the sample holder.

Although in FIG. 2 the X-micromotion mechanism is installed on the rotation tube 20, a similar mechanism may be set on or above the outer cylinder 38. In such case, the aforesaid slip mechanism is no longer necessary because the X-micromotion mechanism moves integrally respect to the Z- and Y-axis driving.

[Introducing Sample Holder into Column]

An operation of introducing the sample holder 2 into column 1 will be explained. The sample holder 2 with a sample 3 attached thereto is introduced up to a position shown in FIG. 3. This position is determined by a positioning pin 5 attached to the sample holder 3. At this position, a vacuum pump, not shown, is used to perform vacuum evacuation of the interior of inner cylinder 33. After the pressure within inner cylinder 33 becomes substantially the same as the pressure in the column 1, rotation is performed while letting the longitudinal direction of sample holder 2 be an axis therefor. At this time, the inner cylinder 33 and slider tube 30 also rotate together, thereby causing a bevel gear provided on the left side of inner cylinder 2 to open a valve 34. Thereafter, as shown in FIG. 2, the sample holder 2 is driven to move toward the X-direction minus side until the holder step-difference part and the holder-touching part come into contact. Typically, this position is approximately the point of origin of the sample movement mechanism.

[Regarding O-ring Deformation]

An explanation will be given of the O-ring that is provided in the sample holder in the event of introducing the sample holder 2. The O-ring is required to secure a prespecified crush amount in order to isolate the vacuum from the atmosphere pressure. By elastic force which is almost proportional to this crush amount, friction force acts on the O-ring and the inner wall of slider tube 30; so, the O-ring is deformed to have a shape which is pulled and tensioned toward the X-direction plus-side as shown in FIG. 4. The O-ring's X-directional deformation serves to deform the holder 2 as a result of application of the force that pushes the sample holder in X-direction. Although this deformation is on the order of nanometers, it gives rise to the sample drift phenomenon-i.e., the sample behaves to move in the operator's unintended directions-at magnifications suitable for direct observation of atoms using electron microscope.

O-ring distortion removing schemes include one conceivable way which follows. The deformed O-ring is forced to move in a direction indicated by arrow x in FIG. 3 and then fixed in a state that the distortion amount becomes zero. In this state, the elastic force based on the deformation of O-ring occurs isotropically in the vertical direction to the axis of longitudinal direction of the holder; thus, the elastic force that produces sample drifts does not work in any way.

[O-ring Distortion Removing Method]

As shown in FIG. 5, a method is effective which is for moving the sample holder in such a way as to exhibit sine-wave attenuation with the origin in X-direction of the sample movement device being as its center. Such sample holder movement may be performed by an operator of holder-introducing device. To move the sample holder with increased accuracy as shown in FIG. 5, the following two techniques are conceivable. (1) A method for providing another linear mechanism separate from the linear mechanism for moving in X-direction as shown in FIG. 2 and for using it to directly apply the force to the holder, (2) a method for driving the linear mechanism which moves it in X-direction as shown in FIG. 2 to thereby drive the sample holder in X-direction at an acceleration which resists or counters the force of being drawn into the column at atmosphere pressure. In this case, while letting the holder-touching part and the holder be in contact, it moves in a direction that the holder-touching part and the slider tube relatively depart from each other. As a result, the holder and slider tube relatively deform, causing the O-ring's distortion to be released.

By supporting the holder-touching part 40 by elastic material 31 in this way, it becomes possible to press in an X-axis minus direction than the finally determined position, thereby making it possible to reduce the O-ring's distortion by the aforesaid technique. The elastic material 31 is required to have a spring constant large enough to counter the force that causes the sample holder to be drawn into the column under atmosphere pressure.

[Slider Tube and Holder-Touching Part]

Another embodiment of the holder-touching part 40 for slider tube 30 will be explained using FIG. 6. Raised portions 50 are provided at one end of the slider tube 30. The elastic material 31 is arranged to act to push the holder-touching part 40 against the raised portions 50. By doing so, it becomes possible to make the holder's finally determined position coincide with the slider tube at all times. In the event of driving the sample holder in X-axis, the slider tube 30 and elastic material 31 plus sample holder 2 move together in an integrated manner because the elastic material 31 has a sufficiently large spring constant than that for countering the atmosphere pressure. The raised portions 50 are arranged to establish point contact with the holder-touching part while using a chosen material, such as sapphire or the like, in order to retain the rigidity.

Another embodiment is shown in FIG. 7. The holder-touching part is installed on the atmosphere side and is tightly coupled through elastic material 31. In this FIG. 7, the elastic material 31 acts to compress against a stopper being integral with the slider tube 30. Alternatively, the touching part per se may be an elastic material.

Although the mechanism for supporting the holder-touching part 40 by elastic material 31 was described so far, when the positional relationship of the holder-touching part 40 and slider tube 30 is changeable, it becomes possible to alleviate the distortion of O-ring. Hence, the elastic material shown in FIG. 1 may alternatively be an actuator which permits the position relationship of holder-touching part 40 and slider tube 30 to become changeable. Examples of this actuator include, but not limited to, a linear actuator and a supersonic motor.

[Holder Fixation Direction]

The sample holder 2 is fixed in the perpendicular direction to the holder's longitudinal direction by means of a member provided at the spherical support point 37 fixed at the X-direction minus-side leading end of the outer cylinder 38. This member is made of sapphire having enhanced abrasion resistance. Desirably, the member is arranged to fix the sample holder 2 by use of three or more points. The holder's X-direction plus-side rear end is also fixed by a similar method using a member provided at the outer cylinder 38.

Regarding a contact point(s) of the holder and the holder-touching part 40 also, it is desirable from a viewpoint of thermal insulation of the holder 2 to make them come into point-contact by semispherical sapphire or the like. Desirably, more than one contact point is provided.

### REFERENCE SIGNS LIST

1 . . . Column, 2 . . . Holder, 3 . . . Sample, 4 . . . 0-Ring for Holder, 5 . . . Holder-Positioning Pin, 10 . . . X-Driving Linear Mechanism, 20 . . . Rotation Tube, 21 . . . Z-Driving Linear Mechanism, 22 . . . Z-Spring, 23 . . . Bearing, 24 . . . Base, 25 . . . Lever Mechanism, 30 . . . Slider Tube, 31 . . . Elastic material, 32 . . . Bellows, 33 . . . Inner Cylinder, 34 . . . Valve, 35 . . . Valve Fixation Part, 36 . . . Spherical Surface Bracket, 37 . . . Spherical Supporting Point, 38 . . . Outer Cylinder, 39 . . . Holder Guide, 40 . . . Holder-Touching Part, 41 . . . Pin, 50 . . . Raised Portion.

1. An electron microscope with a sample holder being inserted into a column, the electron microscope comprising:
an O-ring which makes airtight said column of the electron microscope and said sample holder;
a slider tube which slides in a longitudinal direction of said sample holder and performs positioning of the sample holder in the longitudinal direction;
a bellows which makes airtight said slider tube and said column;
a driving unit which drives the slider tube in the longitudinal direction of the sample holder;
a touching member which performs position determination of the sample holder in the longitudinal direction; and
a sample movement device which has an elastic material for connection of said touching member and said slider tube.

2. The electron microscope of claim 1, further comprising
a drive mechanism which drives said sample holder in such a way as to perform damped vibration in the direction of insertion of said sample holder.

3. The electron microscope of claim 1, further comprising
a fixing member which returns the sample holder to a position for removal of distortion of said O-ring and fixes said sample holder at a position at which the distortion of said O-ring disappears.

4. The electron microscope of claim 1, further comprising
one or more than one raised portion provided at a leading end of said slider tube and in that said raised portion is compressed against said touching member.

5. The electron microscope of claim 1, wherein said touching member is disposed on atmosphere pressure side.

6. A sample movement device of an electron microscope comprising:
an O-ring which makes airtight said column of the electron microscope and said sample holder;
a slider tube which slides in a longitudinal direction of said sample holder and performs positioning of the sample holder in the longitudinal direction;
a bellows which makes airtight said slider tube and said column;
a driving unit which drives the slider tube in the longitudinal direction of the sample holder;
a touching member which performs position determination of the sample holder in the longitudinal direction; and
an elastic material which performs connection of said touching member and said slider tube.

7. The sample movement device of claim 6, further comprising
a drive mechanism which drives said sample holder in such a way as to perform damped vibration in a direction of insertion of said sample holder.
